(19) United States
(12) Patent Application Publication
(10) Pub. No.: US 2006/0023432 A1
(43) Pub. Date: Feb. 2, 2006

(54) Printed circuit board and method for producing such a printed circuit board

(75) Inventors: Jens Florian Hockel, Munchen (DE); Patrick Muller, Karlsfeld (DE)

Correspondence Address: COHEN, PONTANI, LIEBERMAN & PAVANE, Suite 1210, 551 Fifth Avenue, New York, NY, 10176, US

(73) Assignee: Patent-Treuhand-Gesellschaft fur elektrische Gluhlampen mbH, Munich (DE)

(21) Appl. No.: 11/191,733

(22) Filed: Jul. 28, 2005

(30) Foreign Application Priority Data
Jul. 30, 2004 (DE) 10 2004 036 960.7

(51) Int. Cl. H05K 7/06

(52) U.S. Cl. 361/748

(57) ABSTRACT

A printed circuit board having a thermally conductive and electrically insulating layer (1) at the top side of the printed circuit board (6), and a heat conducting element (2) which thermally connects the layer (1) to the underside of the printed circuit board (6). Furthermore, a method for producing such a printed circuit board (6) is described.

### RELATED APPLICATIONS

This patent application claims the priority of German patent application 10 2004 036 960.7, filed Jul. 30, 2004, the disclosure content of which is hereby incorporated by reference.

### FIELD OF THE INVENTION

The invention relates to a printed circuit board. Furthermore, the invention relates to a method for producing a printed circuit board.

### BACKGROUND OF THE INVENTION

The document DE 102 349 95 A1 discloses a light emitting diode arrangement in which a light emitting diode component is fixed on an electrically conductive connection board. The electrically conductive connection board comprises a carrier body, in which is arranged an insert that conducts heat better than the material of the carrier body.

### SUMMARY OF THE INVENTION

It is an object of the present invention to provide a printed circuit board having improved heat conducting properties.

Another object of the invention to provide a method for producing such a printed circuit board.

These and other objects are attained in accordance with one aspect of the present invention directed to a printed circuit board having a thermally conductive and electrically insulating layer. The thermally conductive and electrically insulating layer is situated, for example, at the top side of the printed circuit board, and a heat conducting element thermally connects the layer to the underside of the circuit board.

The printed circuit board has, for example, a basic body containing an electrically insulating material. Patterned conductor tracks containing an electrically conductive material are applied to at least parts of the surface of the basic body of the printed circuit board. By way of example, a component that is to be fixed on the printed circuit board can be electrically contact-connected via the conductor tracks.

The printed circuit board furthermore has a heat conducting element. The heat conducting element connects the thermally conductive and electrically insulating layer to the underside of the printed circuit board.

For this purpose, there is preferably an areal contact between the layer and at least one part of the surface of the heat conducting element. By means of this areal contact, the layer is thermally coupled to the heat conducting element, so that heat can transfer from the layer—preferably by means of heat conduction—to the heat conducting element. The heat is passed on to the underside of the printed circuit board by the heat conducting element, preferably once again for the most part by means of heat conduction.

In this context, “for the most part by means of heat conduction” means that other mechanisms of heat emission, such as thermal radiation for example, are also possible. However, these portions are of secondary importance and, at most, contribute a negligibly small proportion to the heat emission.

From the heat conducting element, the heat may be emitted to the underside of the printed circuit board and from there be distributed areally over the underside of the printed circuit board. However, it is also possible for the heat from the heat conducting element to be emitted for example to a heat sink fitted on the underside of the printed circuit board, without previously being distributed in the area of the underside of the printed circuit board.

In one embodiment of the printed circuit board, the thermally conductive and electrically insulating layer contains at least one material having an electrical resistivity of at least 10² Ωm. The layer preferably has an electrical resistivity of at least 10⁵ Ωm, particularly preferably of at least 10⁹ Ωm.

The material furthermore has a thermal conductivity of at least 100 W/mK, preferably of at least 300 W/mK, particularly preferably of at least 600 W/mK.

In one embodiment of the printed circuit board, the material is additionally distinguished by a hardness of at least 2 according to Mohs' scale. The hardness is preferably at least 5, particularly preferably at least 8. The hardness of pure diamond is 10 according to this scale.

In a further exemplary embodiment of the printed circuit board, the thermally conductive and electrically insulating layer additionally has a microhardness according to Vickers of at least 500 kg/mm², preferably of at least 1000 kg/mm², particularly preferably of at least 2000 kg/mm².

The layer is furthermore preferably particularly temperature-resistant in that it is not harmed by high temperatures. The layer is temperature-resistant in air up to at least 150° C.; the layer is preferably temperature-resistant up to at least 250° C., particularly preferably up to at least 350° C.

The layer may also be distinguished by high corrosion resistance. The layer is particularly preferably resistant to salts, acids and alkaline solutions.

To summarize, the layer at least exhibits very good thermal conduction, very good electrical insulation or is particularly resistant mechanically, for example to scratches. The layer preferably has at least two of the properties mentioned. The layer is particularly preferably distinguished by the fact that it exhibits very good thermal conduction, very good electrical insulation and is additionally particularly resistant mechanically. In addition, the layer is preferably particularly temperature- and corrosion-resistant.

In one embodiment of the printed circuit board, the thickness of the thermally conductive and electrically insulating layer is between 1 μm and 3 μm. In this case, the layer thickness is adapted, for example, to the dielectric constant of the layer material. It is preferably chosen to be thick enough that an electrical breakdown during operation of a component fixed on the printed circuit board can, as far as possible, be prevented.

For this purpose, the layer may contain diamondlike carbon, for example. Diamondlike carbon (DLC) is distinguished by a particularly good thermal conductivity, a high electrical resistance and a high mechanical loading capacity. The thermal conductivity of diamondlike carbon is up to 700 W/mK, the electrical resistivity is approximately 10¹⁰ Ωm, the dielectric constant is approximately 8, the Mohs' hardness of diamondlike carbon is 9, and the Vickers hardness of a layer containing diamondlike carbon is between 2000 and 5000 kg/mm².

In addition to diamondlike carbon, however, layers made of other materials such as, for example, other diamondlike materials (diamondlike nanocomposites—DLN) are also conceivable.

In a preferred embodiment of the printed circuit board, the heat conducting element connects the thermally conductive and electrically insulating layer to the underside of the printed circuit board on a direct path. That is to say that the heat conducting element constitutes a thermal connection between the layer and the underside of the printed circuit board in the case of which heat entering the heat conducting element at the layer, for example, can be passed on to the underside of the printed circuit board on a substantially straight path. In this case, “substantially straight” means that a part of the heat entering the heat conducting element at the layer may be emitted laterally, for example, to the basic body of the printed circuit board. However, a large part of the heat is forwarded directly from the top side of the printed circuit board to the underside of the printed circuit board by the heat conducting element.

In a further embodiment of the printed circuit board, the thermally conductive and electrically insulating layer is provided by a coating of at least one part of the surface of the heat conducting element. By way of example, that part of the surface of the heat conducting element which is situated on the side of the top side of the printed circuit board is coated.

The coating of the heat conducting element may be effected for example by means of a plasma coating method such as PECVD (Plasma Enhanced Chemical Vapor Deposition). A layer produced in this way is distinguished particularly by its uniform thickness and homogeneous composition.

In one embodiment of the printed circuit board, the heat conducting element contains a semiconductor material or a metal. The heat conducting element preferably contains copper, for example. The heat conducting element particularly preferably consists of copper.

In a further embodiment of the printed circuit board, the printed circuit board has a perforation in which the heat conducting element is arranged. The perforation may be, for example, a hole through the printed circuit board. The heat conducting element is, for example, plugged into the perforation. For mechanical fixing, the heat conducting element may be adhesively bonded to the basic body of the printed circuit board, for example, by means of a thermally stable adhesive. However, other types of fixing such as soldering, for example, are also possible in order to fix the heat conducting element in the perforation.

The printed circuit board may be a commercially available FR4 printed circuit board coated with copper on both sides. This has the advantage that the printed circuit board described is a particularly cost-effective alternative to metal core printed circuit boards (MCPCBs) which are usually used in connection with components generating a great deal of heat.

In a further embodiment, the printed circuit board is coated with a thermally conductive and electrically insulating material at its underside. This underside coating preferably covers both the underside of the basic body of the printed circuit board and the heat conductor at least partially.

There is preferably a connection between that region of the underside coating which covers the heat conducting element and the region which covers the remaining underside of the printed circuit board. In this way, it is possible to distribute the heat emitted by the heat conductor on the underside of the printed circuit board. The heat can then be emitted from the underside to the surroundings over a particularly large area. By way of example, the printed circuit board may be thermally coupled to a heat sink by its underside, so that the heat is emitted from the underside of the printed circuit board to the heat sink over a large area.

The underside coating particularly preferably has a thickness of between 1 μm and 3 μm. Such a small thickness of the underside coating contributes to the heat being distributed preferably areally on the underside.

The underside coating contains diamondlike carbon, for example. In addition to the good thermal conductivity and the high electrical resistance, the underside coating is then additionally also distinguished by a high mechanical resistance which affords protection of the printed circuit board against being stratched, for example. In this case, the underside coating is preferably applied on the underside of the printed circuit board by means of a plasma coating method.

In addition to diamondlike carbon, however, layers made of other materials such as, for example, other diamondlike materials (diamondlike nanocomposites—DLN) are also usable.

Furthermore, an optoelectronic arrangement is provided, which has one of the above-described printed circuit boards and an optoelectronic component.

The optoelectronic component is preferably in contact with the thermally conductive and electrically insulating layer at least in places in that at least some parts of the optoelectronic component are in contact with the insulating layer. For this purpose, the layer may be provided, for example, by an at least partial coating of that part of the optoelectronic component which is in contact with the heat conducting element.

By way of example, the layer is applied to an area of the component capable of coupling-out a particularly large amount of heat. This may involve, for example, partial regions of a thermal connection part of the optoelectronic component that are freely accessible from the exterior of the component. Moreover, it is also possible for the layer to be applied directly to at least parts of the surface of the semiconductor chip or the semiconductor chips of the optoelectronic component or for the layer to be applied to at least parts of a contact metallization of the semiconductor chip. The heat generated in the chip during operation of the component can be emitted directly to the heat conducting element in this way.

It is also possible for the layer to be situated as a coating on the surface of the heat conducting element and for the optoelectronic component to be free of such a coating. At least one part of the optoelectronic component then bears on the layer or is fixed on the layer. The component may be fixed on the layer for example by means of a thermally stable adhesive or by means of a solder. In this case, it is possible for a thermal connection part of the chip to bear at least partially on the layer. However, it is also possible for at least parts of the semiconductor chip to bear directly on the layer.

In a further embodiment of the optoelectronic arrangement, it is additionally possible for at least that part of the optoelectronic component which is in contact with the layer to be at least partially coated with a thermally conductive and electrically insulating material. The coating of the component and the layer are preferably in thermal contact with one another. In this case, the layer may be provided for example by a coating of the surface of the heat conducting element which faces the coating of the component. The coating of the optoelectronic component preferably contains diamondlike carbon. Particularly preferably, both the layer on the heat conducting element and the coating of the optoelectronic component contain diamondlike carbon. Particularly preferably, both layers comprise diamondlike carbon.

In addition to diamondlike carbon, however, layers made of other materials such as, for example, other diamondlike materials (diamondlike nanocomposites—DLN) are also usable.

In a further embodiment of the optoelectronic arrangement, the component has an electrical power consumption of at least 1 W. Such components customarily generate a high heat output during operation. Therefore, it is necessary to take measures to dissipate the heat from the component particularly rapidly and efficiently. The printed circuit board specified constitutes in this case a particularly cost-effective alternative to the metal core printed circuit boards that are usually used.

Another aspect of the invention is directed to a method for producing a printed circuit board. For this purpose, firstly a printed circuit board is provided. The printed circuit board may be for example a commercially available printed circuit board (PCB), such as, for example, an FR4 board coated with copper on both sides.

The subsequent method step involves producing a perforation in the printed circuit board. The perforation may be produced, for example, by means of drilling through or stamping through the printed circuit board.

After this method step, a heat conducting element is introduced into the perforation. The heat conducting element is preferably fixed in the perforation of the printed circuit board. This can be done, for example, by means of adhesively bonding it on using a thermally stable adhesive or by soldering on the heat conducting element. The heat conducting element is, for example, a copper lamina or a copper rivet. The copper lamina is preferably coated with a thermally conductive and electrically insulating material at least at its surface facing the top side of the printed circuit board. This layer particularly preferably contains diamondlike carbon.

In a further method step, the underside of the printed circuit board may be coated with diamondlike carbon. This layer preferably covers both the heat conducting element and the remaining surface of the underside of the printed circuit board at least partially. In this way, the heat conducting element can be coupled to the remaining underside of the printed circuit board in a manner exhibiting particularly good conduction.

The use of a body coated with diamondlike carbon for dissipating the heat from an optoelectronic component is furthermore described. The body may be a heat conducting element, by way of example. The heat conducting element preferably contains a material exhibiting good thermal conduction and is coated with diamondlike carbon at least at one of its surfaces. However, the body may also be the optoelectronic component, which is coated with diamondlike carbon in places. In this case, the component is preferably coated at areas of the component via which a particularly large amount of heat can be emitted to the surroundings. Thus, by way of example, a thermal connection part of the component may be coated with diamondlike carbon. However, it is also possible for parts of the surface of the semiconductor chip, of the chip carrier or of a contact metallization of the chip to be coated with diamondlike carbon.

### BRIEF DESCRIPTION OF THE DRAWINGS

The printed circuit board described here is explained in more detail below with reference to exemplary embodiments and the associated figures.

FIG. 1 shows a schematic sectional illustration of a first exemplary embodiment of a printed circuit board described here.

FIG. 2 shows a schematic sectional illustration of a second exemplary embodiment of a printed circuit board described here.

FIG. 3 shows an exemplary embodiment of the optoelectronic arrangement described here.

FIG. 4 shows a perspective sectional illustration of an exemplary embodiment of a housing of a light emitting diode such as may be used in the optoelectronic arrangement.

### DETAILED DESCRIPTION OF THE DRAWINGS

In the exemplary embodiments and figures, identical and identically acting constituent parts are in each case provided with the same reference symbols. The constituent parts illustrated and also the relative sizes of the constituent parts with respect to one another are not to be regarded as true to scale. Rather, some details of the figures have been illustrated with an exaggerated size in order to afford a better understanding.

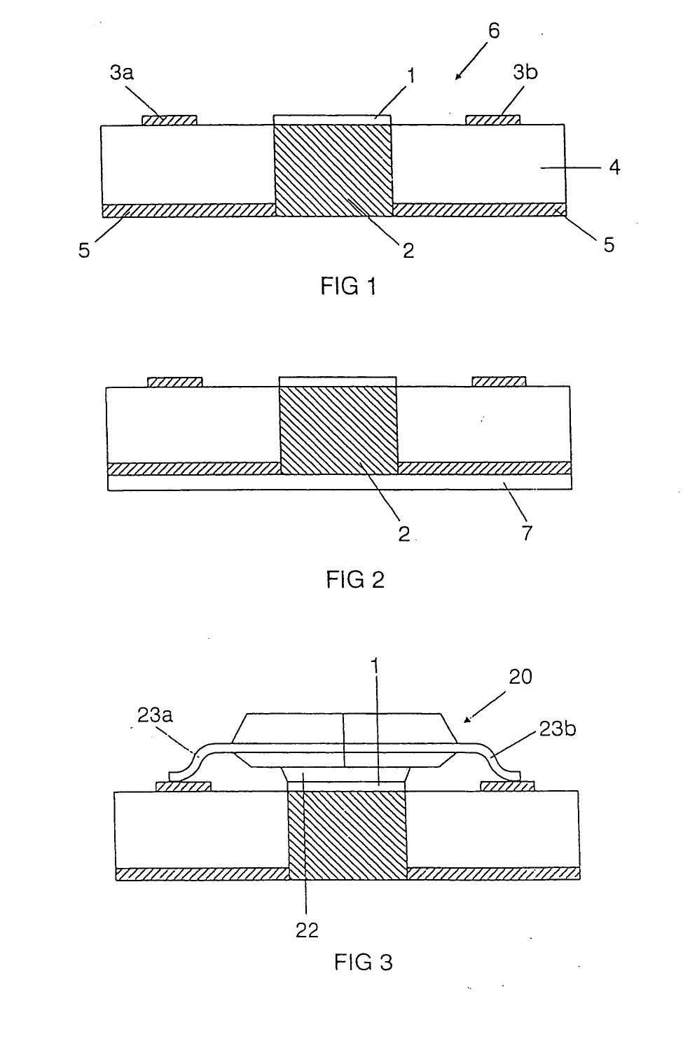

FIG. 1 shows a sectional illustration of a first exemplary embodiment of a printed circuit board described here. The printed circuit board 6 has a basic body 4 made of FR4, for example. By way of example, the printed circuit board 6 is provided by an FR4 printed circuit board coated with copper on both sides. However, other printed circuit board materials such as FR2, FR3, CEM1, CEM2, Teflon, aramid or other materials are also conceivable as a basic body of the printed circuit board.

In this case, the basic body preferably has a thickness of between 1.4 and 2.4 mm. The electrical connection locations 3a, 3b are applied to the basic body 4. They serve for connecting and making electrical contact with a component. The connection locations 3a, 3b preferably contain copper. A copper layer 5 may be applied to the underside of the basic body 4 of the printed circuit board.

The printed circuit board 6 furthermore has a perforation, for example a hole, into which a heat conducting element 2 is inserted. For mechanical fixing to the basic body 4, the heat conducting element 2 is, for example, thermally stably adhesively bonded or soldered on. In this case, the diameter of the heat conducting element 2 preferably corresponds to the diameter of the hole. The diameter may preferably be adapted to the area of the thermal connection part 22 of a component 20 to be mounted onto the printed circuit board 6 (see FIG. 3). The diameter of the heat conducting element 2 is between 3 and 5 mm, for example.

The heat conducting element 2 is preferably provided by a copper lamina. The heat conducting element 2 is preferably a solid body comprising copper. As an alternative, however, it is also possible for the heat conducting element to comprise another material exhibiting good thermal conduction.

In the present exemplary embodiment, a thermally conductive and electrically insulating layer 1 is applied to the heat conducting element 2. The layer 1 comprises diamondlike carbon (DLC) and is applied by means of a plasma coating method. The thickness of the layer 1 is preferably approximately 2 μm. It has an electrical resistivity of approximately 10¹⁰ Ωm and a thermal conductivity of 500 to 700 W/mK. The layer considerably improves the thermal coupling of an optoelectronic component 20 connected to the layer 1 and of the heat conducting element 2. There is a fixed mechanical connection between the layer 1 and the heat conducting element 2. With the aid of the layer, it is possible to reduce the thermal resistance for the section from the thermal connection part 22 of the optoelectronic component 20 to the underside of the printed circuit board, with the use of a heat conducting element made of copper, to approximately 0.1 K/W. This is approximately 1/10 of the thermal resistance without a thermally conductive and electrically insulating layer 1. Only the heat conducting element 2 then makes an appreciable contribution to the thermal resistance of the arrangement.

FIG. 2 shows a further exemplary embodiment of the printed circuit board described. In this case, an underside coating 7 is applied on the underside of the printed circuit board 6. The underside coating 7 preferably comprises diamondlike carbon. Its thickness is preferably between 1 μm and 3 μm. The underside coating 7 advantageously covers the underside of the printed circuit board 6 as completely as possible. As a result, the underside coating 7 also preferably completely covers the underside of the heat conducting element 2. On the one hand, the underside coating 7 serves for areally distributing the heat passing through the heat conducting element 2 on the underside of the printed circuit board 6. On the other hand, the underside coating 7 improves the thermal coupling between printed circuit board 6 and a heat sink to which the printed circuit board 6 may be applied for example by its underside. In this case, as shown in FIG. 2, the underside coating 7 also covers the copper layer 5 as completely as possible.

It is also possible, moreover, for only the heat conducting element 2 to have an underside coating 7 at its underside and for the remaining underside of the printed circuit board 6 to be uncoated. In this way, heat can be emitted directly to a heat sink by the heat conducting element 2 without the heat previously being distributed areally on the underside 7 of the printed circuit board.

FIG. 3 shows an exemplary embodiment of the optoelectronic arrangement described. An optoelectronic arrangement with a light emitting diode 20 is shown here by way of example. The electrical connection parts 23a, 23b of the light emitting diode are for example soldered onto the connection locations 3a, 3b of the printed circuit board 6. The thermal connection part 22 of the light emitting diode is soldered or thermally stably adhesively bonded onto the thermally conductive and electrically insulating layer 1. As an alternative, the layer 1 is formed by a coating of the thermal connection part 22 of the light emitting diode. The layer 1 is then adhesively bonded or soldered onto the heat conducting element 2, by way of example. Moreover, both the light emitting diode 20 at its thermal connection part 22 and the heat conducting element 2 may have a thermally conductive and electrically insulating layer 1.

The light emitting diode 20 is preferably a high-power light emitting diode having a power consumption of at least 1 W. In this case, the light emitting diode 20 may be suitable, for example, for the emission of white light.

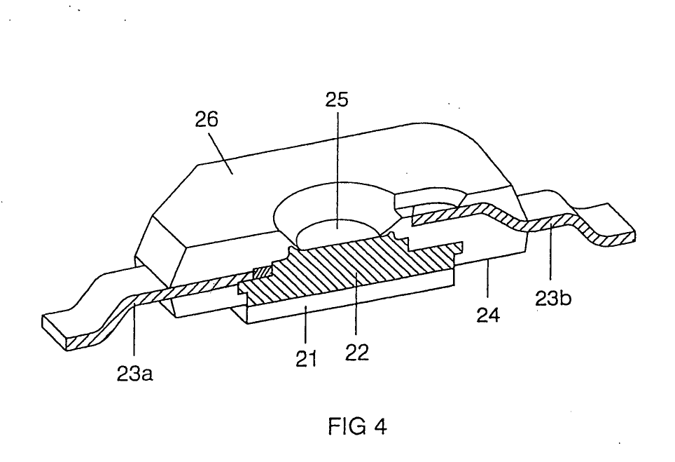

FIG. 4 shows a perspective sectional illustration of a housing of a light emitting diode 20 described here. The housing has a basic body 26, for example, which may comprise a plastic moulding composition and may be produced for example by means of an injection moulding or transfer moulding method. The moulding composition contains, for example, a plastic material based on an epoxy resin or an acrylic resin. The thermal connection part and also the electrical connection parts 23a, 23b are embedded into the basic body 26. The chip mounting region 25, on which a light emitting diode chip can be mounted, is situated on the thermal connection part 22.

The light emitting diode chip may be, for example, a light emitting diode chip of thin-film design in the case of which the growth substrate is removed and the heat generated during operation of the chip is emitted to the thermal connection part 22 via a carrier (not shown but, as is well known, this refers to a suitable layer bonded to the side of the chip facing away from the growth substrate after the latter has been removed) exhibiting particularly good thermal conduction. A thin-film light emitting diode chip may be distinguished in particular by the following characteristic features:
a reflective layer is applied or formed at a first main area of a radiation-generating epitaxial layer sequence that faces toward a carrier element, said reflective layer reflecting at least a part of the electromagnetic radiation generated in the epitaxial layer sequence back into the latter;
the epitaxial layer sequence has a thickness in the region of 20 μm or less, in particular in the region of 10 μm; and
the epitaxial layer sequence contains at least one semiconductor layer with at least one area having a disordering structure that ideally leads to an approximately ergodic distribution of the light in the epitaxial layer sequence, i.e. it has an as far as possible ergodically stochastic scattering behaviour.

A basic principle of a thin-film light emitting diode chip is described for example in I. Schnitzer et al., Appl. Phys. Lett. 63 (16), Oct. 18, 1993, 2174-2176, the disclosure content of which in this respect is hereby incorporated by reference.

A thin-film light emitting diode chip is to a good approximation a Lambert surface radiator and is, therefore, particularly well suited to application in a headlight.

The thermal connection part 22 is electrically contact-connected for example with the electrical connection part 23b. The thermal connection part 22 preferably contains a material exhibiting good electrical and thermal conduction, such as copper for example. The connection part 22 preferably comprises copper.

The underside of the thermal connection location 22 may be coated with a layer 21 made of diamondlike carbon. For this purpose, the underside of the thermal connection part 22 preferably projects slightly beyond the underside 24 of the basic body 26. The layer 21 may be either an additional coating with diamondlike carbon or the layer 1. Owing to its high electrical resistance, the layer 21 also contributes to the electrical decoupling of the light emitting diode in addition to its very good heat conducting property.

The invention is not restricted by the description on the basis of the exemplary embodiments. Rather, the invention comprises any new feature and also any combination of features, in particular any combination of features in the patent claims, even if this feature or this combination itself is not explicitly specified in the patent claims or exemplary embodiments.

We claim:

1. A printed circuit board, comprising:
a thermally conductive and electrically insulating layer (1) at a top side of the printed circuit board (6); and
a heat conducting element (2), which thermally connects said layer (1) to an underside of the printed circuit board (6).

2. The printed circuit board according to claim 1, in which the layer (1) contains at least one material having an electrical resistivity of at least 10² Ωm and a thermal conductivity of at least 10² W/mK.

3. The printed circuit board according to claim 1, in which the layer (1) contains diamondlike carbon.

4. The printed circuit board according to claim 1, in which the layer (1) has a thickness of between 1 μm and 3 μm.

5. The printed circuit board according to claim 1, in which the heat conducting element (2) connects the layer (1) to the underside of the printed circuit board (6) on a direct path.

6. The printed circuit board according to claim 1, in which the layer (1) is coated on at least one part of a surface of the heat conducting element (2).

7. The printed circuit board according to claim 1, in which the heat conducting element (2) contains a metal.

8. The printed circuit board according to claim 1, in which the printed circuit board (6) has a perforation in which the heat conducting element (2) is arranged.

9. Printed circuit board according to claim 1, in which the printed circuit board (6) contains at least one of the following materials: copper, FR4.

10. The printed circuit board according to claim 1, in which the underside of the printed circuit board (6) is at least partially coated with a thermally conductive and electrically insulating material (7).

11. The printed circuit board according to claim 10, in which the underside coating (7) of the printed circuit board (6) contains diamondlike carbon.

12. The printed circuit board according to claim 10, in which the underside coating (7) of the printed circuit board (6) has a thickness of between 1 μm and 3 μm.

13. An optoelectronic arrangement, comprising:
a printed circuit board (6) according to claim 1 and an optoelectronic component (20), which is in contact with the layer at least in places.

14. The optoelectronic arrangement according to claim 13, in which the layer (1) is coated on at least that part of the optoelectronic component (20) which is in contact with the heat conducting element (2).

15. The optoelectronic arrangement according to claim 13, in which at least that part of the optoelectronic component (20) which is in contact with the layer (1) is coated with a thermally conductive and electrically insulating material (21).

16. The optoelectronic arrangement according to claim 15, in which the coating (21) of the optoelectronic component (20) contains diamondlike carbon.

17. The optoelectronic arrangement according to claim 13, in which the optoelectronic component (20) has an electrical power consumption of at least one watt.

18. The optoelectronic arrangement according to claim 13, in which the optoelectronic component (20) is one of the following components: light emitting diode, laser diode.

19. A method for producing a printed circuit board, comprising:
a) providing a printed circuit board (6);
b) producing a perforation in the printed circuit board (6);
c) introducing a heat conducting element (2) into the perforation of the printed circuit board (6); and
d) coating (7) of at least parts of an underside of the printed circuit board (6) with diamondlike carbon.

20. Use of a body (2, 22) coated with diamondlike carbon for dissipating the heat from an optoelectronic component.

21. Use according to claim 20, wherein the body (2, 22) comprises copper.
